(19) United States
(12) Patent Application Publication
(10) Pub. No.: US 2011/0297423 A1
(43) Pub. Date: Dec. 8, 2011

(54) PRINTED CIRCUIT BOARD AND METHOD OF MANUFACTURING THE SAME

(75) Inventors: Seung Hyun NOH, Daejeon (KR); Dong Uk LEE, Chungcheoungbuk-do (KR); Chin Kwan KIM, Daejeon (KR)

(73) Assignee: SAMSUNG ELECTRO-MECHANICS CO., LTD., Gyunggi-do (KR)

(21) Appl. No.: 13/155,333

(22) Filed: Jun. 7, 2011

(30) Foreign Application Priority Data
Jun. 7, 2010 (KR) 10-2010-0053450

(51) Int. Cl. H05K 1/02; H05K 3/06; B05D 5/12

(52) U.S. Cl. 174/250; 427/97.4; 216/13

(57) ABSTRACT

Disclosed is a printed circuit board, including a base substrate, a first bump including a first metal layer formed on the base substrate and a second metal layer formed on the first metal layer, and a second bump including a third metal layer formed on the base substrate, in which the first bump has a height greater than that of the second bump. Because the heights of the first bump and the second bump are different, even when the printed circuit board warps, an electrical connection between the printed circuit board and an external substrate does not become broken. A method of manufacturing the printed circuit board is also provided.

### CROSS REFERENCE TO RELATED APPLICATION

This application claims the benefit of Korean Patent Application No. 10-2010-0053450, filed Jun. 7, 2010, entitled “A printed circuit board and a method of manufacturing the same”, which is hereby incorporated by reference in its entirety into this application.

### BACKGROUND OF THE INVENTION

1. Technical Field

The present invention relates to a printed circuit board (PCB) and a method of manufacturing the same.

2. Description of the Related Art

Typically, a PCB is manufactured by forming a copper wiring pattern on either or both sides of a board made of any type of thermosetting synthetic resin, mounting ICs or electronic components on the board with electrical connections therebetween, and encapsulating the board with an insulator.

The recent trend for multi-functionality and high speed of electronic products is gaining momentum. In order to cope with such trend, a semiconductor chip, and a semiconductor chip mounting PCB for connecting the semiconductor chip to a main substrate are developing very rapidly.

The requirements of the development of PCBs are closely related to the high speed and high density of PCBs. In order to satisfy such requirements, there is a need to mainly improve and develop the fabrication of PCBs to make them light, slim, short and small, form fine circuitry, and have superior electrical properties, high reliability, high signal transmission structure, etc.

FIG. 1 is a cross-sectional view showing a conventional PCB 10, and FIG. 2 is a cross-sectional view showing the PCB 10 of FIG. 1 which is stacked with an external substrate 20. With reference to FIGS. 1 and 2, the conventional PCB 10 is described below.

As shown in FIG. 1, the conventional PCB 10 includes a base substrate 11, bumps 12 and a solder resist layer 16.

The base substrate 11 is composed of an insulating layer or a build-up layer, and the bumps 12 are formed at the same height on the base substrate 11. The bumps 12 are composed of a seed layer 13, a patterned metal layer 14, and a surface treatment layer 15, and are used to electrically connect the PCB 10 with an external device or an external substrate. Furthermore, the solder resist layer 16 having openings 17 that externally expose the bumps 12 is formed on the outermost surface of the base substrate 11.

However, the conventional PCB 10 is problematic because warpage may occur. In particular, as shown in FIG. 2, when the PCB 10 is stacked with the external substrate 20, disconnection may occur. Specifically, in the case where the distance d1 between both ends of the PCB 10 and both ends of the external substrate 20 becomes longer than the distance d2 between the center of the PCB 10 and the center of the external substrate 20 attributable to warpage, the bumps 12 have the same height and thus the connection of the bumps 12 and the solder balls 21 between both ends of the PCB 10 and both ends of the external substrate 20 may become broken, undesirably causing a disconnection. In contrast, in the case where the distance d2 between the center of the PCB 10 and the center of the external substrate 20 becomes longer than the distance d1 between both ends of the PCB 10 and both ends of the external substrate 20, the connection of the bumps 12 and the solder balls 21 located at the center of the PCB 10 and the center of the external substrate 20 may undesirably become broken.

### SUMMARY OF THE INVENTION

Accordingly, the present invention has been made keeping in mind the problems encountered in the related art and the present invention is intended to provide a PCB, in which a bump connection between the PCB and an external substrate does not become broken even when the PCB warps, and also to provide a method of manufacturing the same.

An aspect of the present invention provides a PCB, including a base substrate, a first bump including a first metal layer formed on the base substrate and a second metal layer formed on the first metal layer, and a second bump including a third metal layer formed on the base substrate, in which the height of the first bump is greater than the height of the second bump.

In this aspect, the PCB may further include a protective layer having openings that externally expose the first bump and the second bump.

Furthermore, the protective layer may include a solder resist.

In this aspect, the PCB may further include a seed layer formed between the first metal layer and the second metal layer of the first bump and formed between the third metal layer of the second bump and the base substrate.

In this aspect, the PCB may further include a primer layer formed on a surface of the base substrate.

In this aspect, the second metal layer and the third metal layer may include the same metal, and may be formed using the same process.

In this aspect, the PCB may further include a surface treatment layer formed on the second metal layer of the first bump and the third metal layer of the second bump.

Another aspect of the present invention provides a method of manufacturing a PCB, including (A) forming a patterned first metal layer on a base substrate, and (B) simultaneously forming a second metal layer having a pattern corresponding to the first metal layer on the first metal layer, and forming a patterned third metal layer on the base substrate, thus forming a first bump including the first metal layer and the second metal layer and a second bump including the third metal layer.

In this aspect, (A) may include (A1) providing a base substrate composed of a primer layer formed on either or both sides thereof and a first metal layer formed on the primer layer, and (A2) patterning the first metal layer using etching.

In this aspect, in (B), the second metal layer and the third metal layer may be formed using plating.

In this aspect, (B) may include (B1) forming a seed layer on the base substrate including the patterned first metal layer, (B2) performing plating on the seed layer, thus simultaneously forming a second metal layer on the seed layer formed on the first metal layer and forming a third metal layer on the seed layer formed on the base substrate, so that a first bump including the first metal layer, the seed layer formed on the first metal layer and the second metal layer formed on the seed layer, and a second bump including the seed layer formed on the base substrate and the third metal layer formed on the seed layer are formed, and (B3) removing the seed layer which is externally exposed.

In this aspect, the method may further include (C) forming a protective layer having openings that externally expose the first bump and the second bump.

Furthermore, the protective layer may include a solder resist.

In this aspect, the first bump may have a height greater than that of the second bump.

In this aspect, the method may further include (C) forming a surface treatment layer on the second metal layer of the first bump and the third metal layer of the second bump.

### BRIEF DESCRIPTION OF THE DRAWINGS

The features and advantages of the present invention will be more clearly understood from the following detailed description taken in conjunction with the accompanying drawings, in which:

FIG. 1 is a cross-sectional view showing a conventional PCB;

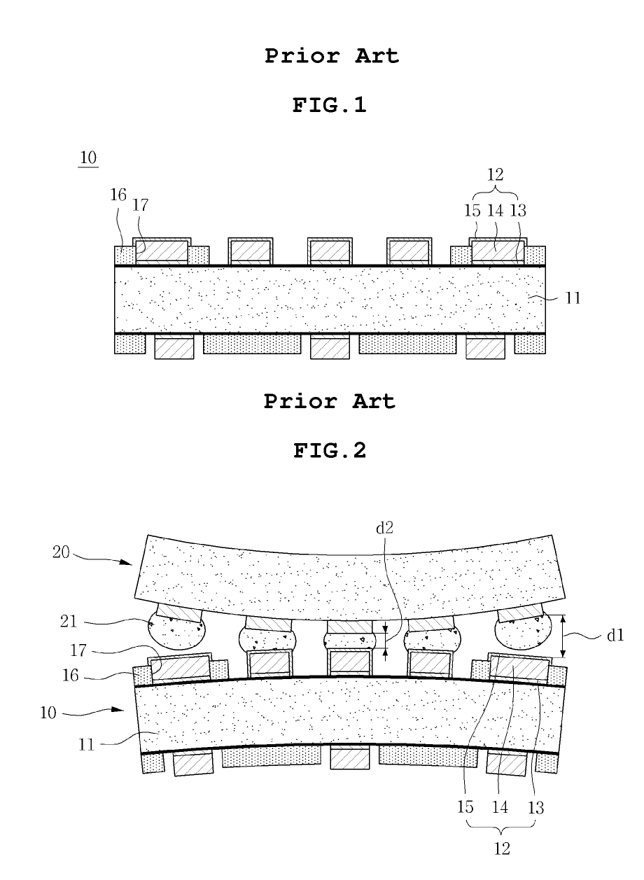

FIG. 2 is a cross-sectional view showing the PCB of FIG. 1 which is stacked with an external substrate;

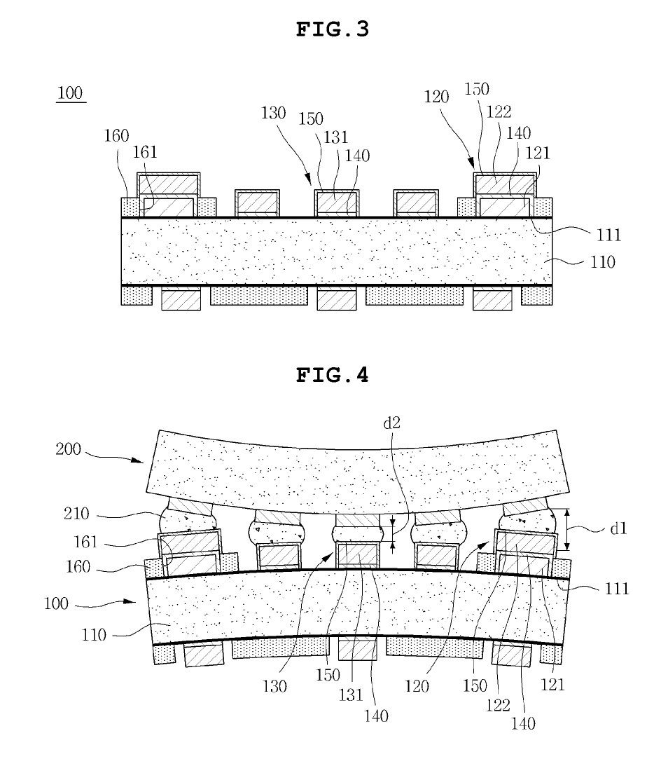

FIG. 3 is a cross-sectional view showing a PCB according to an embodiment of the present invention;

FIG. 4 is a cross-sectional view showing the PCB of FIG. 3 which is stacked with an external substrate; and

FIGS. 5 to 11 are cross-sectional views showing a process of manufacturing the PCB of FIG. 3.

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. In the description, the terms “first”, “second” and so on are used to distinguish one element from another element, and the elements are not defined by the above terms. Moreover, descriptions of known techniques, even if they are pertinent to the present invention, are regarded as unnecessary and may be omitted when they would make the characteristics of the invention and the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

PCB

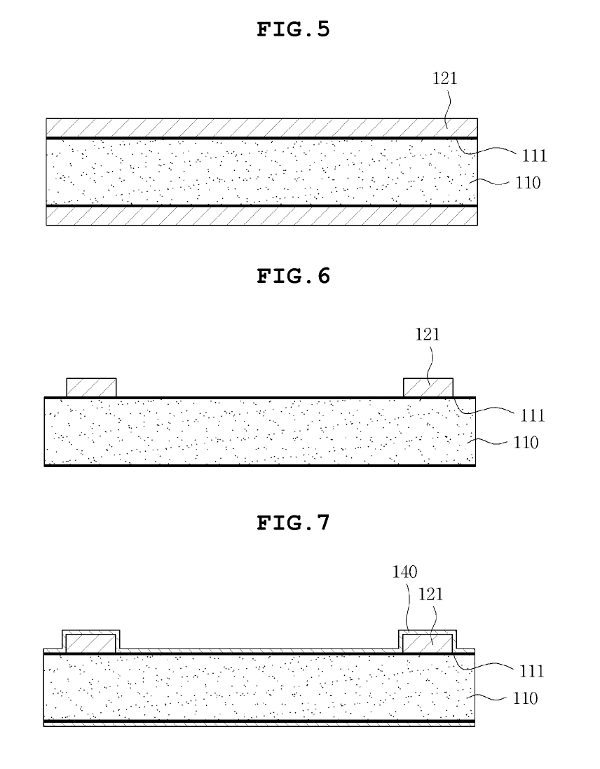

FIG. 3 is a cross-sectional view showing a PCB according to an embodiment of the present invention. With reference thereto, the PCB 100 according to the present embodiment is described below.

As shown in FIG. 3, the PCB 100 according to the present embodiment includes a base substrate 110, and a first bump 120 and a second bump 130, which are formed on the base substrate 110, provided that the height of the first bump 120 is greater than the height of the second bump 130.

The base substrate is a base member of the PCB 100.

Although FIG. 3 illustrates the base substrate 110 composed of a single insulating layer, the present invention is not limited thereto. The base substrate 110 may be formed of a build-up layer composed of multiple or single insulating and circuit layers, and vias. As such, in the case when the base substrate 110 is composed of an insulating layer, it may include a composite polymer resin typically used as an interlayer insulating material. For example, a prepreg may be used as the base substrate 110, so that a PCB 100 is manufactured to be thinner. Alternatively, ABF (Ajinomoto Build up Film) may be used as the base substrate 110 thus facilitating the formation of fine circuitry. In addition, an epoxy resin such as FR-4, BT (Bismaleimide Triazine), etc., may be used, but the present invention is not particularly limited thereto.

On the other hand, a primer layer 111 may be further formed on the surface of the base substrate 110. The primer layer 111 is used to enhance a bonding force between the base substrate 110 and the first metal layer 121 or between the base substrate 110 and the third metal layer 131, and may be made of a material having superior adhesion. For example, the primer layer 111 may be formed of polyester, polyurethane, polyacrylate, silicone acrylic resin, methacrylic resin, acrylic resin, melamine resin, polysiloxane resin, etc. Alternatively, as a member including the base substrate 110 and the primer layer 111 together, a primer coated foil including a specific polymer formed on a BT resin to enhance a bonding force with metal and a metal layer formed on the polymer may be used, and the metal layer may be etched, thus forming the patterned first metal layer 121.

The first bump 120 is used to electrically connect the PCB 100 with an external device or an external substrate, and includes the first metal layer 121 and the second metal layer 122.

The first metal layer 121 is formed in a state of being patterned on the base substrate 110. Because the first bump 120 includes the first metal layer 121, the first bump 120 may be formed to have a height greater than that of the second bump 130. The first metal layer 121 forms the first bump 120 to thus achieve an electrical connection with the outside, and for example may be made of an electrically conductive metal such as gold, silver, copper, nickel and so on.

The second metal layer 122 may be formed on the first metal layer 121 to have a pattern corresponding to the first metal layer 121. The second metal layer 122 may be formed in the same process using the same metal as that of a third metal layer 131 which will be described later. The second metal layer 122 may form the first bump 120 together with the first metal layer 121, and may be made of an electrically conductive metal.

Also, a seed layer 140 may be further formed between the first metal layer 121 and the second metal layer 122. The seed layer 140 may be formed thin between the first metal layer 121 and the second metal layer 122 so as to facilitate the formation of the second metal layer 122.

Also, a surface treatment layer 150 may be further formed on the surface of the first bump 120, namely, on the second metal layer 122, in order to improve electrical properties and durability. The surface treatment layer 150 may be formed by subjecting the externally exposed surface of the second metal layer 122 to electric or electroless tin plating, OSP treatment, or HASL treatment.

The first bump 120 may function alone as an external connection terminal, or an additional solder ball (not shown) may be formed on the first bump 120 to achieve a connection with a semiconductor chip, an active device, a passive device, an external substrate, etc.

The second bump 130 is used to electrically connect the PCB 100 with an external device or an external substrate, like the first bump 120, and includes the third metal layer 131.

The second bump 130 includes the third metal layer 131 which is patterned in the same process as the formation of the second metal layer 122, and is formed to be lower than the first bump 120. The third metal layer 131 which is formed in the same process as in the second metal layer 122 may be made of the same metal as that of the second metal layer 122. Also a seed layer 140 which is the same as the seed layer 140 of the first bump 120 may be further formed between the third metal layer 131 and the base substrate 110. Also, a surface treatment layer 150 may be further formed on the externally exposed surface of the third meal layer 131.

Also, a protective layer 160 may be further formed on the base substrate 110 having the first bump 120 and the second bump 130.

The protective layer 160 is used to protect the base substrate 110, the first bump 120, and the second bump 130. The protective layer 160 which is the outermost layer of the PCB 100 may be made of for example a solder resist such as a liquid solder resist. Furthermore, openings 161 may be formed in the protective layer 160 to externally expose the first bump 120 and the second bump 130.

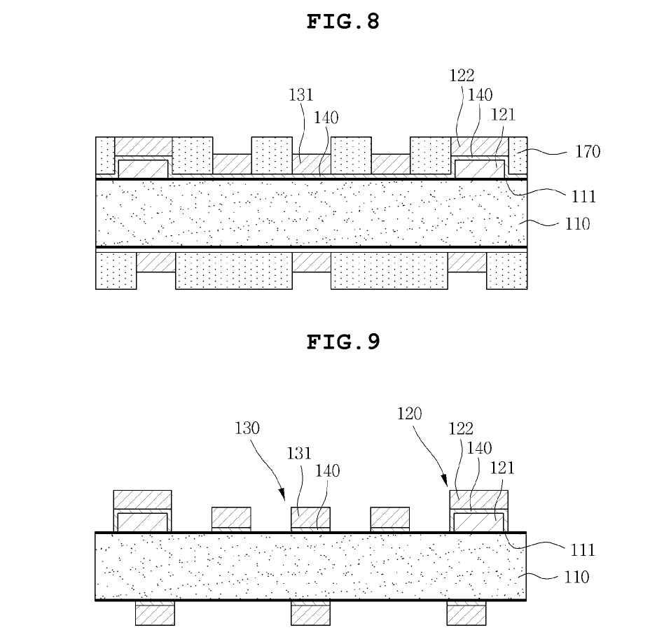

FIG. 4 is a cross-sectional view showing the PCB 100 of FIG. 3 which is stacked with an external substrate 200. This is explained below.

As shown in FIG. 4, the external substrate 200 may be stacked on the PCB 100, and warpage may occur with time. As such, the case where the heights of the first bump 120 and the second bump 130 are different as in the PCB 100 according to the present embodiment may compensate for any disconnection that might result from warping. For example, in the case where the distance d1 between both ends of the PCB 100 and both ends of the external substrate 200 becomes longer than the distance d2 between the center of the PCB 100 and the center of the external substrate 200 attributable to warpage, the height of the first bump 120 is greater than that of the second bump 130, and thus an electrical connection of the first bump 120 and the solder ball 210 formed between both ends of the PCB 100 and both ends of the external substrate 200 may not become broken, and electrical conduction may be ensured by means of the first bump 120. Such a connection enables a three-dimensional electrical connection utilizing the space.

Because the height of the first bump 120 is determined by the height of the first metal layer 121, the height of the first metal layer 121 may be adjusted depending on the degree of warpage of the PCB 100, thus preventing a poor connection between the first bump 120 and the solder ball 210.

Furthermore, in the case where warpage between the PCB 100 and the external substrate 200 is not severe, it is possible to mount a passive device such as MLCC between the second bump 130 and the external substrate 200, so that the heights of the first bump 120 and the second bump 130 may be adjusted.

The case where the distance d1 between both ends of the PCB 100 and both ends of the external substrate 200 is longer than the distance d2 between the center of the PCB 100 and the center of the external substrate 200 is illustrated in the present embodiment. In contrast, in the case where the distance d2 between the center of the PCB 100 and the center of the external substrate 200 is longer, the first bump 120 may be formed at the center of the PCB 100 so as to compensate for any disconnection. The external substrate 200 is not limited to the substrate, but may include an interposer or semiconductor chip.

Method of Manufacturing PCB

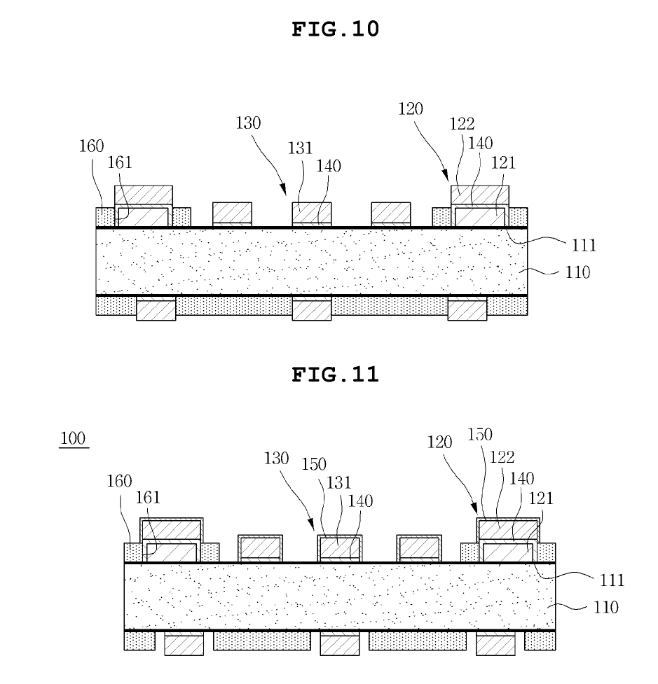

FIGS. 5 to 11 are cross-sectional views showing a process of manufacturing the PCB 100 of FIG. 3. With reference thereto, the method of manufacturing the PCB 100 according to the present embodiment is described below.

As shown in FIGS. 5 and 6, a patterned first metal layer 121 is formed on a base substrate 110.

Specifically, a base substrate 110 composed of a primer layer 111 formed on either or both sides thereof and a first metal layer 121 formed on the primer layer 111 is provided. Thereafter, an etching resist (not shown) is formed on the first metal layer 121, an etching solution is applied on the first metal layer 121, and the etching resist (not shown) is then removed, and thus the first metal layer 121 is patterned.

In the present embodiment, the patterned first metal layer 121 may be formed using a subtractive process, but the use of a semi-additive process is possible.

Next, as shown in FIG. 7, a seed layer 140 is formed on the base substrate 110 having the patterned first metal layer 121.

As such, the seed layer 140 may be formed on the base substrate 110 and on the upper surface of the first metal layer 121, using electroless plating such as sputtering.

Next, as shown in FIGS. 8 and 9, a second metal layer 122 and a third metal layer 131 are formed using the same process on the seed layer 140, thus forming a first bump 120 and a second bump 130, and the externally exposed seed layer 140 is removed.

The second metal layer 122 and the third metal layer 131 may be formed using a single plating process. For example, a plating resist 170 is formed on the seed layer 140, and the same plating process is performed thus forming the second metal layer 122 on the seed layer 140 formed on the first metal layer 121, and the third metal layer 131 on the seed layer 140 formed on the base substrate 110. Thereafter, the plating resist 170 is removed, whereby the first bump 120 including the first metal layer 121, the seed layer 140 formed on the first metal layer 121 and the second metal layer 122 formed on the seed layer 140, and the second bump 130 including the seed layer 140 formed on the base substrate 110 and the third metal layer 131 formed on the seed layer 140 may be formed. As such, the second metal layer 122 and the third metal layer 131 may be formed using a single process and thus have a uniform height. Hence, the first bump 120 may be formed to be taller than the second bump 130 because of the height of the first metal layer 121. Furthermore, because the second metal layer 122 and the third metal layer 131 are formed using a single plating process, the process time and cost may be reduced, thus ensuring process convenience.

When the first bump 120 and the second bump 130 are completed, the externally exposed seed layer 140 becomes unnecessary and thus may be removed using etching.

Next, as shown in FIG. 10, a protective layer 160 having openings 161 that externally expose the first bump 120 and the second bump 130 is formed on the base substrate 110.

As such, the protective layer 160 may include a solder resist. The solder resist is applied only on a portion of the base substrate 110 where the first bump 120 and the second bump 130 are not formed, and thus openings 161 that externally expose the first bump 120 and the second bump 130 may be formed while forming the protective layer 160. Alternatively, a protective layer 160 may be formed over the entire surface of the base substrate 110 including the first bump 120 and the second bump 130, and then the protective layer 160 of the portion where the first bump 120 and the second bump 130 are formed may be removed using laser or etching, thus forming openings 161.

Next, as shown in FIG. 11, a surface treatment layer 150 is formed on the surface of the first bump 120 and the second bump 130.

As such, the surface treatment layer 150 may be formed on the externally exposed surface of the second metal layer 122 that forms the first bump 120 and the externally exposed surface of the third metal layer 131 that forms the second bump 130.

Thereby, the PCB 100 according to the embodiment of the present invention as shown in FIG. 11 is manufactured.

Although the case where the second metal layer 122 and the third metal layer 131 are formed using a semi-additive process is illustrated in the present embodiment, the present invention is not limited thereto and a subtractive process or an additive process may be applied.

As described hereinbefore, the present invention provides a PCB and a method of manufacturing the same. According to the present invention, even when the PCB warps, the first bump which has a height greater than that of the second bump is formed at the region in which the distance between the PCB and an external substrate becomes longer, thus preventing disconnection.

Also, according to the present invention, because the heights of the first and second bumps are different, a passive device can be mounted on the second bump which has a low height.

Also, according to the present invention, a primer layer is formed on the surface of the base substrate, thus enhancing a bonding force between the base substrate and the first metal layer or between the base substrate and a third metal layer.

Also, according to the present invention, because the second metal layer and the third metal layer can be formed using a single process, the process time and cost can be reduced, thus ensuring process convenience.

Although the embodiments of the present invention regarding the PCB and the method of manufacturing the same have been disclosed for illustrative purposes, those skilled in the art will appreciate that a variety of different modifications, additions and substitutions are possible, without departing from the scope and spirit of the invention as disclosed in the accompanying claims Accordingly, such modifications, additions and substitutions should also be understood as falling within the scope of the present invention.

What is claimed is:

1. A printed circuit board, comprising:
a base substrate;
a first bump including a first metal layer formed on the base substrate and a second metal layer formed on the first metal layer; and
a second bump including a third metal layer formed on the base substrate, wherein the first bump has a height greater than that of the second bump.

2. The printed circuit board as set forth in claim 1, further comprising a protective layer having openings that externally expose the first bump and the second bump.

3. The printed circuit board as set forth in claim 2, wherein the protective layer comprises a solder resist.

4. The printed circuit board as set forth in claim 1, further comprising a seed layer formed between the first metal layer and the second metal layer of the first bump and formed between the third metal layer of the second bump and the base substrate.

5. The printed circuit board as set forth in claim 1, further comprising a primer layer formed on a surface of the base substrate.

6. The printed circuit board as set forth in claim 1, wherein the second metal layer and the third metal layer comprise a same metal, and are formed using a same process.

7. The printed circuit board as set forth in claim 1, further comprising a surface treatment layer formed on the second metal layer of the first bump and the third metal layer of the second bump.

8. A method of manufacturing a printed circuit board, comprising:
(A) forming a patterned first metal layer on a base substrate; and
(B) simultaneously forming a second metal layer having a pattern corresponding to the first metal layer on the first metal layer and forming a patterned third metal layer on the base substrate, thus forming a first bump including the first metal layer and the second metal layer and a second bump including the third metal layer.

9. The method as set forth in claim 8, wherein (A) comprises:
(A1) providing a base substrate comprising a primer layer formed on either or both sides thereof and a first metal layer formed on the primer layer; and
(A2) patterning the first metal layer using etching.

10. The method as set forth in claim 8, wherein in (B) the second metal layer and the third metal layer are formed using plating.

11. The method as set forth in claim 8, wherein (B) comprises:
(B1) forming a seed layer on the base substrate including the patterned first metal layer;
(B2) performing plating on the seed layer, thus simultaneously forming a second metal layer on the seed layer formed on the first metal layer and forming a third metal layer on the seed layer formed on the base substrate, so that a first bump including the first metal layer, the seed layer formed on the first metal layer and the second metal layer formed on the seed layer and a second bump including the seed layer formed on the base substrate and the third metal layer formed on the seed layer are formed; and
(B3) removing the seed layer which is externally exposed.

12. The method as set forth in claim 8, further comprising (C) forming a protective layer having openings that externally expose the first bump and the second bump.

13. The method as set forth in claim 12, wherein the protective layer comprises a solder resist.

14. The method as set forth in claim 8, wherein the first bump has a height greater than that of the second bump.

15. The method as set forth in claim 8, further comprising (C) forming a surface treatment layer on the second metal layer of the first bump and the third metal layer of the second bump.
